(19) United States
(12) Patent Application Publication
(10) Pub. No.: US 2025/0255106 A1
(43) Pub. Date: Aug. 7, 2025

(54) DISPLAY DEVICE AND METHOD OF FABRICATING THE SAME

(71) Applicant: Samsung Display Co., LTD., Yongin-si (KR)

(72) Inventors: Dong Min LEE, Yongin-si (KR); Joon Yong PARK, Yongin-si (KR); Su Kyoung YANG, Yongin-si (KR); Hyun Eok SHIN, Yongin-si (KR)

(21) Appl. No.: 18/894,940

(22) Filed: Sep. 24, 2024

(30) Foreign Application Priority Data
Feb. 5, 2024 (KR) 10-2024-0017147

(51) Int. Cl. H10K 59/122; H10K 59/12; H10K 59/80

(52) U.S. Cl. CPC H10K 59/122; H10K 59/1201; H10K 59/873

(57) ABSTRACT

A display device according to one or more embodiments of the present disclosure includes a substrate having an emission area and a non-emission area; an anode electrode positioned on the emission area; a pixel defining layer defining a first opening; a bank structure defining a second opening and including a first and second bank layer; a light emitting layer; a cathode electrode; a first encapsulation layer positioned on the cathode electrode and contacting the first bank layer; and a second encapsulation layer positioned on the first encapsulation layer, wherein the second bank layer has a side surface facing the first opening, wherein the first encapsulation layer has a side surface facing the second bank layer, wherein the side surface of the second bank layer faces the side surface of the first encapsulation layer with a gap interposed therebetween, and wherein the gap is filled with the second encapsulation layer.

### CROSS-REFERENCE TO RELATED APPLICATION

The present application claims priority to and the benefit of Korean Patent Application No. 10-2024-0017147, filed on Feb. 5, 2024, in the Korean Intellectual Property Office, the entire disclosure of which is incorporated herein by reference.

### BACKGROUND

### 1. Field

Aspects of the present disclosure relate to a display device and a method of fabricating the same.

### 2. Description of the Related Art

As the information society develops, the demand for display devices for displaying images has increased and diversified. For example, display devices have been applied to various electronic devices, such as smartphones, digital cameras, laptop computers, navigation devices, and smart televisions. The display devices may be flat panel display devices, such as liquid crystal display devices, field emission display devices, or organic light emitting display devices. Among such flat panel display devices, a light emitting display device may display an image without a backlight unit providing light to a display panel because each of the pixels of the display panel includes light emitting elements that may emit light by themselves.

Recently, as various electronic devices develop, the demand for high-resolution display devices has increased. Since the high-resolution display device requires a high degree of integration of pixels, an interval between light emitting elements overlapping respective emission areas may be reduced. Accordingly, the high-resolution display device may be formed by a pattern process of forming individual pixels rather than a mask process.

The above information disclosed in this Background section is only for enhancement of understanding of the background of the invention and therefore it may contain information that does not form the prior art.

### SUMMARY

Aspects of the present disclosure are directed to a display device capable of having high resolution and having improved device reliability, by forming light emitting elements through a photo pattern process without a mask.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Detailed contents of other embodiments are described in a detailed description and are illustrated in the drawings.

According to some embodiments of the present disclosure, there is provided a display device including: a substrate having an emission area and a non-emission area; an anode electrode positioned on the emission area of the substrate; a pixel defining layer positioned on the non-emission area of the substrate and defining a first opening; a bank structure positioned on the pixel defining layer, defining a second opening, and including a first bank layer and a second bank layer; a light emitting layer positioned on the anode electrode; a cathode electrode positioned on the light emitting layer; a first encapsulation layer positioned on the cathode electrode and in contact with the first bank layer; and a second encapsulation layer positioned on the first encapsulation layer, wherein the second bank layer has a side surface facing the first opening, wherein the first encapsulation layer has a side surface facing the second bank layer, wherein the side surface of the second bank layer faces the side surface of the first encapsulation layer with a gap interposed therebetween, and wherein the gap is filled with the second encapsulation layer.

In some embodiments, the side surface of the second bank layer and the side surface of the first encapsulation layer may be in contact with the second encapsulation layer.

In some embodiments, the first encapsulation layer may overlap the emission area, and may not overlap the non-emission area.

In some embodiments, the second bank layer may include at least one of tungsten, titanium nitride, or molybdenum.

In some embodiments, the second bank layer may include a tip protruding past a side surface of the first bank layer toward the first opening.

In some embodiments, the protruding tip of the second bank layer may be entirely in contact with the first encapsulation layer and the second encapsulation layer.

In some embodiments, in a plan view, the first opening may be completely surrounded by the second opening.

In some embodiments, the second bank layer further may have a first surface connected to the side surface of the second bank layer and positioned in a direction opposite to a direction in which the first bank layer is positioned, and the first encapsulation layer further may have a second surface positioned at the same plane as the first surface of the second bank layer and positioned to overlap with a protruding tip of the second bank layer, in a direction parallel to the substrate.

In some embodiments, the first surface and the second surface may be spaced apart from each other with the second encapsulation layer interposed therebetween.

In some embodiments, the first surface of the second bank layer may be entirely in contact with the second encapsulation layer.

In some embodiments, the display device may further include a third encapsulation layer positioned on the second encapsulation layer and a fourth encapsulation layer positioned on the third encapsulation layer, wherein the second encapsulation layer includes an inorganic insulating material.

In some embodiments, the display device may further include a third encapsulation layer positioned on the second encapsulation layer, wherein the second encapsulation layer includes an organic material.

In some embodiments, the display device may further include a residual pattern positioned between the anode electrode and the pixel defining layer in a direction perpendicular to the substrate, wherein the residual pattern is in contact with the light emitting layer, and wherein the residual pattern overlaps the protruding tip of the second bank layer.

In some embodiments, a side surface of the first bank layer may be in contact with the light emitting layer, the cathode electrode, and the first encapsulation layer, and the side surface of the first bank layer may be entirely covered by the light emitting layer, the cathode electrode, and the first encapsulation layer.

In some embodiments, the cathode electrode may be electrically connected to the first bank layer.

According to some embodiments of the disclosure, there is provided a method of fabricating a display device, the method including: forming a substrate having an emission area and a non-emission area, forming an anode electrode on the emission area of the substrate and forming a sacrificial layer on the anode electrode; forming a pixel defining layer entirely covering the sacrificial layer and the substrate; forming a bank structure including a first bank layer and a second bank layer that entirely covers the pixel defining layer; forming a photoresist exposing the anode electrode and positioned on the bank structure, and performing a first etching process to remove portions of the bank structure, the pixel defining layer, and the sacrificial layer in a portion where the photoresist is not formed, thereby forming a hole overlapping with the anode electrode; depositing a light emitting layer, a cathode electrode, and a first encapsulation layer on the anode electrode and the bank structure, forming a photoresist on the anode electrode and a portion overlapping a periphery of the anode electrode, and then performing a second etching process to remove the light emitting layer, the cathode electrode, and the first encapsulation layer positioned in a portion where the photoresist is not formed, thereby forming a light emitting element and at the same time, forming a cavity between the second bank layer and the first encapsulation layer in a direction perpendicular to the substrate; and performing a chemical mechanical planarization (CMP) process to remove a portion of the first encapsulation layer, thereby removing the cavity and then forming a second encapsulation layer entirely covering the first encapsulation layer and the second bank layer.

In some embodiments, in the performing of the first etching process, the second bank layer may include a tip protruding past a side surface of the first bank layer toward the hole.

In some embodiments, in the performing of the CMP process, the protruding tip of the second bank layer may be spaced apart from the first encapsulation layer with a space therebetween in a direction parallel to the substrate.

In some embodiments, in the performing of the CMP process, the space formed between the protruding tip of the second bank layer and the first encapsulation layer may be filled with the second encapsulation layer.

In some embodiments, the second bank layer may include at least one of tungsten, titanium nitride, or molybdenum.

A display device according to some embodiments includes a bank structure having tips protruding toward emission areas in a fabricating process of the display device, and thus, light emitting elements positioned to overlap the respective emission areas may be formed. In addition, in the display device according to some embodiments, a cavity formed between the bank structure and a first encapsulation layer may be removed by removing a portion of the first encapsulation layer positioned on the bank structure through a CMP process, in the fabricating process. For this reason, device reliability of the display device according to some embodiments may be improved.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating an electronic device according to some embodiments of the present disclosure;

FIG. 2 is a perspective view illustrating a display device included in the electronic device according to some embodiments of the present disclosure;

FIG. 3 is a schematic cross-sectional view of the display device of FIG. 2, according to some embodiments of the present disclosure;

FIG. 4 is a plan view illustrating an arrangement of emission areas in a display area of FIG. 3, according to some embodiments of the present disclosure;

FIG. 5 is a schematic cross-sectional view of the display area taken along the line X1-X1′ of FIG. 4, according to some embodiments of the present disclosure;

FIG. 6 is a schematic enlarged cross-sectional view of a first emission area in FIG. 5, according to some embodiments of the present disclosure;

FIG. 7 is an enlarged cross-sectional view of area S in FIG. 6, according to some embodiments of the present disclosure;

FIG. 8 is a schematic cross-sectional view of a display layer taken along the line X1-X1′ of FIG. 4 according to some embodiments of the present disclosure;

FIG. 9 is a schematic cross-sectional view of a display layer taken along the line X1-X1′ of FIG. 4 according to some embodiments of the present disclosure;

FIG. 10 is a schematic enlarged cross-sectional view of a first emission area in FIG. 9, according to some embodiments of the present disclosure; and

FIGS. 11 to 23 are cross-sectional views illustrating a schematic method of fabricating a display layer included in the display device of FIG. 5, according to some embodiments of the present disclosure.

### DETAILED DESCRIPTION

The present disclosure will now be described more fully herein with reference to the accompanying drawings, in which some embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the disclosure. Similarly, the second element could also be termed a first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

As used herein, expressions such as “at least one of”, “one of”, and “selected from”, when preceding a list of elements, modify the entire list of elements and do not modify the individual elements of the list. For example, “at least one of a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

Hereinafter, embodiments of the present disclosure will be further described in further detail with reference to the accompanying drawings.

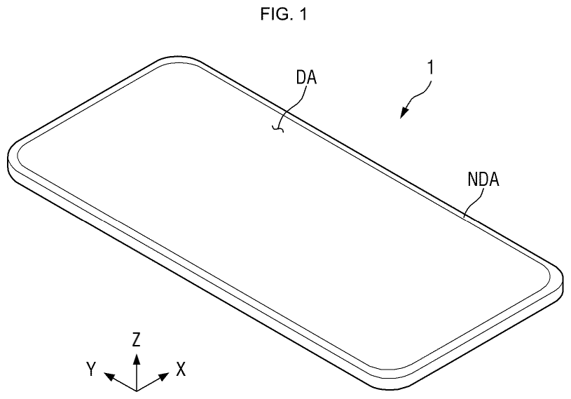

FIG. 1 is a schematic perspective view of an electronic device 1 according to some embodiments of the present disclosure.

Referring to FIG. 1, the electronic device 1 displays a moving image or a still image. The electronic device 1 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, that provide display screens, may be included in the electronic device 1.

In FIG. 1, a first direction (e.g., the X-axis direction), a second direction (e.g., the Y-axis direction), and a third direction (e.g., the Z-axis direction) are defined. The first direction (e.g., X-axis direction) and the second direction (e.g., Y-axis direction) may be perpendicular to each other, the first direction (e.g., X-axis direction) and the third direction (e.g., Z-axis direction) may be perpendicular to each other, and the second direction (e.g., Y-axis direction) and the third direction (e.g., Z-axis direction) may be perpendicular to each other. It may be understood that the first direction (e.g., X-axis direction) refers to a transverse direction in the drawings, the second direction (e.g., Y-axis direction) refers to a longitudinal direction in the drawings, and the third direction (e.g., Z-axis direction) refers to an upward and downward direction (i.e., a thickness direction) in the drawings. In the following specification, unless otherwise specified, the term “direction” may refer to both directions toward both sides extending along the direction. In addition, when both “directions” extending to both sides need to be distinguished from each other, one side will be referred to as “one side in the direction” and the other side will be referred to as “the other side in the direction”. In FIG. 1, a direction to which an arrow indicating a direction is directed will be referred to as one side, and a direction opposite to such a direction will be referred to as the other side.

Hereinafter, for convenience of explanation, in referring to surfaces of the electronic device 1 or respective members constituting the electronic device 1, one surface facing one side in a direction in which an image is displayed, that is, the third direction (e.g., Z-axis direction) will be referred to as an upper surface, and a surface opposite to the one surface will be referred to as the other surface. However, the present disclosure is not limited thereto, and the one surface and the other surface of the member may be referred to as a front surface and a rear surface, respectively, or be referred to as a first surface and a second surface, respectively. In addition, in describing relative positions of the respective members of the electronic device 1, one side in the third direction (e.g., Z-axis direction) may be referred to as an upper portion and the other side in the third direction (e.g., Z-axis direction) may be referred to as a lower portion.

A shape of the electronic device 1 may be variously modified in a suitable manner. For example, the electronic device 1 may have a shape such as a rectangular shape with a width greater than a length, a rectangular shape with a length greater than a width, a square shape, a quadrangular shape with rounded corners (vertices), other polygonal shapes, or a circular shape.

The electronic device 1 may include a display area DA and a non-display area NDA. The display area DA is an area where a screen may be displayed, and the non-display area NDA is an area where the screen is not displayed. The display area DA may also be referred to as an active area, and the non-display area NDA may also be referred to as a non-active area. The display area DA may occupy substantially the center of the electronic device 1.

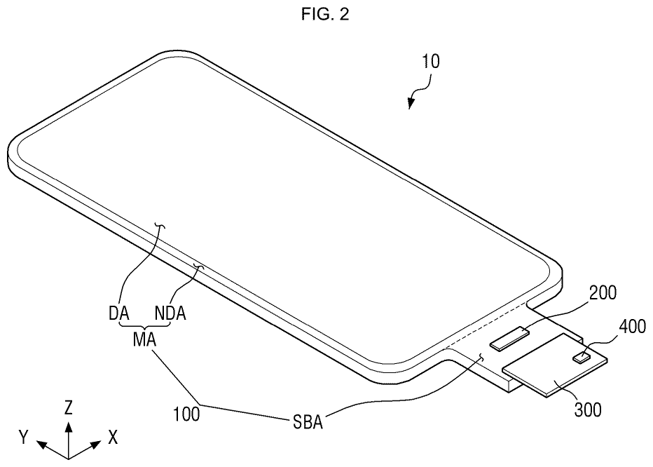

FIG. 2 is a perspective view illustrating a display device 10 included in the electronic device 1 according to some embodiments of the present disclosure.

Referring to FIG. 2, the electronic device 1 according to some embodiments may include a display device 10. The display device 10 may provide a screen displayed on the electronic device 1. Examples of the display device 10 may include an inorganic light emitting diode display device, an organic light emitting display device, a quantum dot light emitting display device, a plasma display panel, a field emission display, and the like. Hereinafter, a case where an organic light emitting diode display device is applied as an example of the display device will be described by way of example, but the present disclosure is not limited thereto, and the same technical spirit may be applied to other display devices if applicable.

The display device 10 may have a shape similar to that of the electronic device 1 in a plan view. For example, the display device 10 may have a rectangular shape, in a plan view, having short sides in a first direction (e.g., X-axis direction) and long sides in a second direction (e.g., Y-axis direction). A corner where the short side in the first direction (e.g., X-axis direction) and the long side in the second direction (e.g., Y-axis direction) meet may be rounded with a curvature, but is not limited thereto, and may also be right-angled. The shape of the display device 10 in a plan view is not limited to the rectangular shape, and may be a shape similar to other polygonal shapes, a circular shape, an elliptical shape, or the like.

The display device 10 may include a display panel 100, a display driver 200, a circuit board 300, and a touch driver 400.

The display panel 100 may include a main area MA and a sub-area SBA. The main area MA may include a display area DA, including pixels displaying an image, and a non-display area NDA disposed around the display area DA.

The display area DA may emit light from a plurality of emission areas or a plurality of openings to be described later. For example, the display panel 100 may include pixel circuits including switching elements, a pixel defining layer defining the emission areas or the openings, and self-light emitting elements. For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto. It has been illustrated in the drawings that the self-light emitting element is an organic light emitting diode.

The non-display area NDA may be an area outside (e.g., surrounding) the display area DA. The non-display area NDA may be defined as an edge area of the main area MA of the display panel 100.

The sub-area SBA may be an area extending from one side of the main area MA. The sub-area SBA may include a flexible material that may be bent, folded, and rolled. For example, when the sub-area SBA is bent, the sub-area SBA may overlap with the main area MA in the thickness direction (e.g., the third direction (e.g., Z-axis direction)). The sub-area SBA may include the display driver 200 and pad parts connected to the circuit board 300. In some embodiments, the sub-area SBA may be omitted, and the display driver 200 and the pad parts may be positioned in the non-display area NDA.

The display driver 200 may output signals and voltages for driving the display panel 100. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be disposed in the sub-area SBA, and may overlap with the main area MA in the thickness direction (e.g., overlap in a plan view) by bending of the sub-area SBA. As another example, the display driver 200 may be mounted on the circuit board 300.

The circuit board 300 may be attached onto the pad parts of the display panel 100 using an anisotropic conductive film (ACF). The circuit board 300 may be a flexible printed circuit board, a printed circuit board, or a flexible film such as a chip on film.

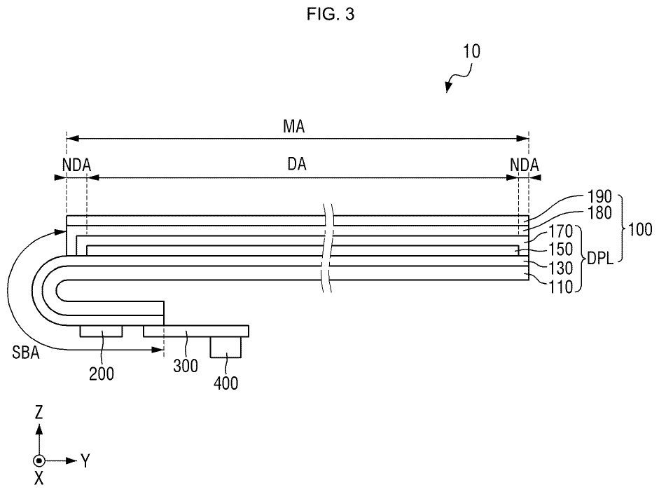

The touch driver 400 may be mounted on the circuit board 300. The touch driver 400 may be connected to a touch sensor layer 180 (see, e.g., FIG. 3) of the display panel 100. The touch driver 400 may be formed as an integrated circuit.

FIG. 3 is a schematic cross-sectional view of the display device 10 of FIG. 2, according to some embodiments of the present disclosure.

Referring to FIG. 3, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate that may be bent, folded, and rolled. As an example, the substrate 110 may include a polymer resin such as polyimide (PI), but is not limited thereto. In some embodiments, the substrate 110 may include a glass material or a metal material.

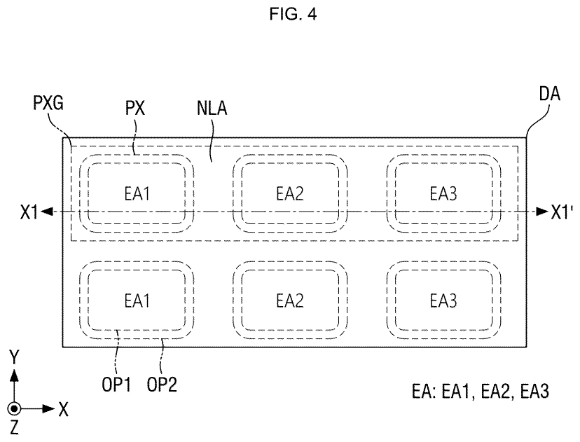

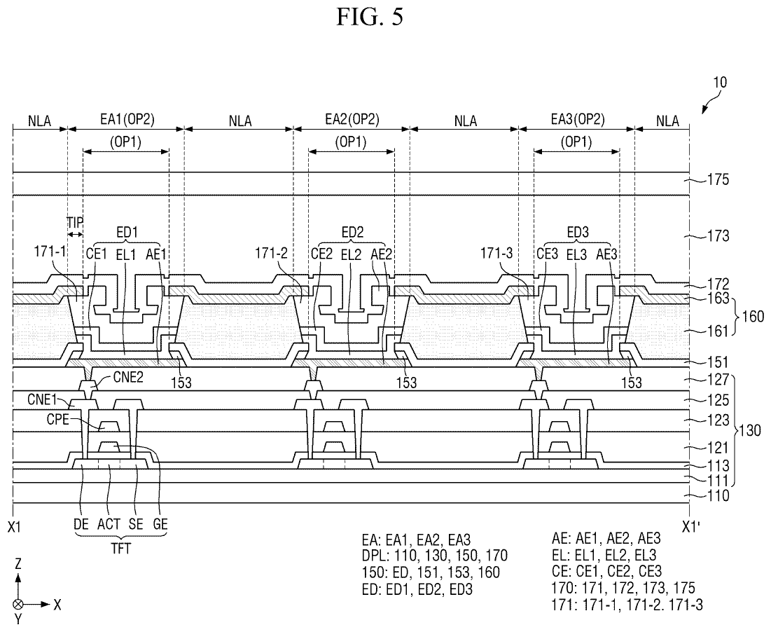

The thin film transistor layer 130 may be disposed on the substrate 110. The thin film transistor layer 130 may be disposed in the display area DA, the non-display area NDA, and the sub-area SBA. The thin film transistor layer 130 may include a plurality of thin film transistors TFT (see, e.g., FIG. 5) constituting a pixel PX (see, e.g., FIG. 4).

The display element layer 150 may be disposed on the thin film transistor layer 130. The display element layer 150 may be positioned to overlap with the display area DA (e.g., in a plan view). The display element layer 150 may include a plurality of light emitting elements ED (see, e g, FIG. 5). As an example, the light emitting element according to some embodiments may include at least one of an organic light emitting diode (LED) including an organic light emitting layer, a quantum dot LED including a quantum dot light emitting layer, an inorganic LED including an inorganic semiconductor, and a micro LED, but is not limited thereto.

The thin film encapsulation layer 170 may be positioned on the display element layer 150. The thin film encapsulation layer 170 may be positioned to overlap with the display area DA and the non-display area NDA. The thin film encapsulation layer 170 may cover an upper surface and side surfaces of the display element layer 150, and may protect the display element layer 150 from external oxygen and moisture.

The touch sensor layer 180 may be disposed on the thin film encapsulation layer 170. The touch sensor layer 180 may be positioned to overlap with the display area DA and the non-display area NDA. The touch sensor layer 180 may sense a user's touch in a mutual capacitance manner or a self-capacitance manner.

The color filter layer 190 may be disposed on the touch sensor layer 180. The color filter layer 190 may be positioned to overlap with the display area DA and the non-display area NDA. The color filter layer 190 may absorb some of light introduced from the outside of the display device 10 to reduce reflected light by external light. Accordingly, the color filter layer 190 may prevent or substantially reduce distortion of colors due to external light reflection.

Since the color filter layer 190 is directly disposed on the touch sensor layer 180, the display device 10 may not require a separate substrate for the color filter layer 190. Accordingly, a thickness of the display device 10 may be relatively small. In addition, the color filter layer 190 may also be omitted according to embodiments.

As illustrated in FIG. 3, a portion of the display layer DPL overlapping with the sub-area SBA may be bent. When a portion of the display layer DPL is bent, the display driver 200, the circuit board 300, and the touch driver 400 may overlap with the main area MA in the third direction (e.g., Z-axis direction).

FIG. 4 is a plan view illustrating an arrangement of emission areas EA in a display area DA of FIG. 3, according to some embodiments of the present disclosure.

Referring to FIG. 4, the display area DA according to some embodiments may include a plurality of first to third emission areas EA1, EA2, and EA3 and a non-emission area NLA. The non-emission area NLA may be positioned to surround the plurality of first to third emission areas EA1, EA2, and EA3.

The non-emission area NLA may block each light emitted from the plurality of first to third emission areas EA1, EA2, and EA3. For this reason, the non-emission area NLA may assist in preventing or substantially reducing the likelihood of each light emitted from the plurality of first to third emission areas EA1, EA2, and EA3 from being mixed with each other. A pixel defining layer 151 (see, e.g., FIG. 5) and a bank structure 160 (see, e.g., FIG. 5) to be described later may be disposed in the non-emission area NLA.

The emission area EA may include a first emission area EA1, a second emission area EA2, and a third emission area EA3 that emit light of different colors. The first to third emission areas EA1, EA2, and EA3 each may emit one of red light, green light, or blue light, respectively, and colors of the light emitted from the first to third emission areas EA1, EA2, and EA3 may be different from each other depending on types of light emitting elements ED to be described later. In some embodiments, the first emission area EA1 may emit the red light, which is light of a first color, the second emission area EA2 may emit the green light, which is light of a second color, and the third emission area EA3 may emit the blue light, which is light of a third color, but the present disclosure is not limited thereto. It has been illustrated in FIG. 4 that sizes or shapes of the first to third emission areas EA1, EA2, and EA3 are the same as each other, but the present disclosure is not limited thereto. That is, sizes and shapes of the first to third emission areas EA1, EA2, and EA3 may be freely adjusted according to suitable characteristics.

The plurality of first to third emission areas EA1, EA2, and EA3 may be defined by first openings OP1 and second openings OP2. As an example, the first openings OP1 may be defined by a pixel defining layer 151 to be described later, and the second openings OP2 may be defined by a bank structure 160 to be described later. In a plan view, the second opening OP2 may completely surround the first opening OP1, and may be completely surrounded by the non-emission area NLA.

In some embodiments, at least one first emission area EA1, at least one second emission area EA2, and at least one third emission area EA3 disposed adjacent to each other may constitute one pixel group PXG. The pixel group PXG may be a minimum unit emitting white light. However, types and/or the number of first to third emission areas EA1, EA2, and EA3 constituting the pixel group PXG may be changed according to embodiments.

FIG. 5 is a schematic cross-sectional view of the display area DA taken along the line X1-X1′ of FIG. 4, according to some embodiments of the present disclosure. FIG. 5 is a partial cross-sectional view of the display device 10 overlapping with the display area DA, and illustrates a schematic cross-section of the display layer DPL. That is, FIG. 5 illustrates cross sections of the substrate 110, the thin film transistor layer 130, the display element layer 150, and the thin film encapsulation layer 170 of the display device 10. The substrate 110 has been described with reference to FIG. 3, and a description thereof will thus be omitted.

Referring to FIG. 5, the thin film transistor layer 130 may be positioned on the substrate 110. The thin film transistor layer 130 may include a first buffer layer 111, thin film transistors TFT, a gate insulating layer 113, a first interlayer insulating layer 121, capacitor electrodes CPE, a second interlayer insulating layer 123, first connection electrodes CNE1, a first via layer 125, second connection electrodes CNE2, and a second via layer 127.

The first buffer layer 111 may be disposed on the substrate 110. The first buffer layer 111 may include an inorganic film capable of preventing or substantially reducing permeation of air or moisture. For example, the first buffer layer 111 may include a plurality of inorganic films that are alternately stacked.

The thin film transistor TFT may be disposed on the first buffer layer 111, and may constitute a pixel circuit connected to each of a plurality of pixels. As an example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be disposed on the first buffer layer 111. The active layer ACT may overlap with the gate electrode GE in the third direction (e.g., Z-axis direction), and may be insulated from the gate electrode GE by the gate insulating layer 113. A material of the active layer ACT in portions of the active layer ACT may become conductors to form the source electrode SE and the drain electrode DE.

The gate electrode GE may be disposed on the gate insulating layer 113. The gate electrode GE may overlap with the active layer ACT (e.g., in a plan view) with the gate insulating layer 113 interposed therebetween.

The gate insulating layer 113 may be disposed on the active layer ACT. The gate insulating layer 113 may cover the active layer ACT and the first buffer layer 111, and may insulate the active layer ACT and the gate electrode GE from each other. The gate insulating layer 113 may include contact holes through which the first connection electrodes CNE1 penetrate.

The first interlayer insulating layer 121 may cover the gate electrodes GE and the gate insulating layer 113. The first interlayer insulating layer 121 may include contact holes through which the first connection electrodes CNE1 penetrate. The contact holes of the first interlayer insulating layer 121 may be connected to the contact holes of the gate insulating layer 113 and contact holes of the second interlayer insulating layer 123.

The capacitor electrodes CPE may be disposed on the first interlayer insulating layer 121. The capacitor electrode CPE may overlap with the gate electrode GE in the third direction (e.g., Z-axis direction). The capacitor electrode CPE and the gate electrode GE may form capacitance.

The second interlayer insulating layer 123 may cover the capacitor electrodes CPE and the first interlayer insulating layer 121. The second interlayer insulating layer 123 may include contact holes through which the first connection electrodes CNE1 penetrate. The contact holes of the second interlayer insulating layer 123 may be connected to the contact holes of the first interlayer insulating layer 121 and the contact holes of the gate insulating layer 113.

The first connection electrodes CNE1 may be disposed on the second interlayer insulating layer 123. The first connection electrode CNE1 may electrically connect the drain electrode DE of the thin film transistor TFT and the second connection electrode CNE2 to each other. The first connection electrode CNE1 may be inserted into the contact holes formed in the first interlayer insulating layer 121, the second interlayer insulating layer 123, and the gate insulating layer 113 to be in contact with the drain electrode DE of the thin film transistor TFT.

The first via layer 125 may cover the first connection electrodes CNE1 and the second interlayer insulating layer 123. The first via layer 125 may planarize an underlying structure. The first via layer 125 may include contact holes through which the second connection electrodes CNE2 penetrate.

The second connection electrodes CNE2 may be disposed on the first via layer 125. The second connection electrodes CNE2 may be inserted into the contact holes formed in the first via layer 125 to be in contact with the first connection electrodes CNE1. The second connection electrodes CNE2 may electrically connect the first connection electrodes CNE1 and first to third anode electrodes AE1, AE2, and AE3 to each other.

The second via layer 127 may cover the second connection electrodes CNE2 and the first via layer 125. The second via layer 127 may include contact holes through which the first to third anode electrodes AE1, AE2, and AE3 penetrate.

The display element layer 150 may be disposed on the second via layer 127. The display element layer 150 may include a light emitting element ED, a pixel defining layer 151, residual patterns 153, and a bank structure 160.

The light emitting element ED according to some embodiments may include a first light emitting element ED1 disposed in a portion overlapping with (e.g., in a plan view) the first emission area EA1, a second light emitting element ED2 disposed in a portion overlapping with the second emission area EA2, and a third light emitting element ED3 disposed in a portion overlapping with the third emission area EA3. The first light emitting element ED1 may include the first anode electrode AE1, a first light emitting layer EL1, and a first cathode electrode CE1. The second light emitting element ED2 may include the second anode electrode AE2, a second light emitting layer EL2, and a second cathode electrode CE2. The third light emitting element ED3 may include the third anode electrode AE3, a third light emitting layer EL3, and a third cathode electrode CE3. The first to third light emitting elements ED1, ED2, and ED3 may emit light of different colors depending on materials of the first to third light emitting layers EL1, EL2, and EL3. For example, the first light emitting element ED1 may emit red light, which is light of a first light, the second light emitting element ED2 may emit green light, which is light of a second color, and the third light emitting element ED3 may emit blue light, which is light of a third color.

The anode electrode AE may be disposed on the second via layer 127. The anode electrode AE may be electrically connected to the drain electrode DE of the thin film transistor TFT through the first connection electrode CNE1 and the second connection electrode CNE2.

The anode electrode AE may include the first anode electrode AE1 disposed in the first emission area EA1, the second anode electrode AE2 disposed in the second emission area EA2, and the third anode electrode AE3 disposed in the third emission area EA3. The first anode electrode AE1, the second anode electrode AE2, and the third anode electrode AE3 may be disposed to be spaced apart from each other on the second via layer 127, respectively.

In some embodiments, the anode electrode AE may have a stacked film structure in which a layer made of a material having a high work function, such as indium tin oxide (ITO), indium zinc oxide (IZO), zinc oxide (ZnO), or indium oxide (In₂O₃), and a layer made of a reflective material, such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or mixtures thereof, are stacked. As an example, the anode electrode AE may have a multilayer structure of ITO/Mg, ITO/MgF, ITO/Ag, and ITO/Ag/ITO, but is not limited thereto.

The pixel defining layer 151 according to some embodiments may be positioned on the second via layer 127 and the anode electrode AE. The pixel defining layer 151 may define the first openings OP1. The pixel defining layer 151 may be entirely disposed on the second via layer 127, but may expose a portion of an upper surface of the anode electrode AE. For example, the pixel defining layer 151 may expose the anode electrode AE in portions thereof overlapping with the first openings OP1 (e.g., in a plan view), and a light emitting layer EL may be directly disposed on the anode electrode AE in the portions of the pixel defining layer 151 overlapping with the first openings OP1 (e.g., in a plan view).

The pixel defining layer 151 may include an inorganic insulating material. As an example, the pixel defining layer 151 may include aluminum oxide, titanium oxide, tantalum oxide, hafnium oxide, zinc oxide, silicon oxide, silicon nitride, and/or silicon oxynitride.

The bank structure 160 according to some embodiments may be positioned on the pixel defining layer 151. The bank structure 160 may define the second openings OP2. The bank structure 160 may include tips TIP protruding toward the emission area EA.

In the display device 10 according to some embodiments, the bank structure 160 includes the tips TIP, and accordingly, the first to third light emitting elements ED1, ED2, and ED3 positioned to overlap with the first to third emission areas EA1, EA2, and EA3, respectively, may be formed without a separate fine metal. A fabricating process will be described later.

The bank structure 160 according to some embodiments may include a first bank layer 161 and a second bank layer 163. The first bank layer 161 and the second bank layer 163 will be described later.

The light emitting layer EL according to some embodiments may be disposed on the anode electrode AE. The light emitting layer EL may be an organic light emitting layer made of an organic material, and may be formed on the anode electrode AE through a deposition process. When the thin film transistor TFT applies a predetermined voltage to the anode electrode AE and the cathode electrode CE receives a common voltage or a cathode voltage, holes and electrons may move to the light emitting layer EL through a hole transporting layer and an electron transporting layer, respectively, and may be combined with each other in the light emitting layer EL to emit light.

The light emitting layer EL may include the first light emitting layer EL1, the second light emitting layer EL2, and the third light emitting layer EL3 respectively disposed in the first to third emission areas EA1, EA2, and EA3. As an example, the first light emitting layer EL1 may be a light emitting layer emitting the red light, which is the light of the first color, the second light emitting layer EL2 may be a light emitting layer emitting the green light, which is the light of the second color, and the third light emitting layer EL3 may be a light emitting layer emitting the blue light, which is the light of the third color, but the present disclosure is not limited thereto.

The light emitting layer EL according to some embodiments may be in contact with the residual patterns 153 on both sides thereof in the first direction (e.g., X-axis direction). The residual pattern 153 will be described later.

The cathode electrode CE according to some embodiments may be disposed on the light emitting layer EL. The cathode electrode CE may include a transparent conductive material to emit the light generated from the light emitting layer EL. The cathode electrode CE may receive a common voltage or a low potential voltage. When the anode electrode AE receives a voltage corresponding to a data voltage and the cathode electrode CE receives the low potential voltage, a potential difference is formed between the anode electrode AE and the cathode electrode CE, such that the light emitting layer EL may emit the light.

In some embodiments, the cathode electrode CE may include a layer made of a material having a small work function, such as Li, Ca, LiF/Ca, LiF/Al, Al, Mg, Ag, Pt, Pd, Ni, Au, Nd, Ir, Cr, BaF, Ba, or compounds or mixtures thereof (e.g., a mixture of Ag and Mg, etc.). The cathode electrode CE may further include a transparent metal oxide layer disposed on the layer made of the material having the small work function.

The cathode electrode CE according to some embodiments may include the first cathode electrode CE1, the second cathode electrode CE2, and the third cathode electrode CE3 positioned to respectively overlap with the first to third emission areas EA1, EA2, and EA3 (e.g., in a plan view). The first to third cathode electrodes CE1, CE2, and CE3 may be spaced apart from each other. The first to third cathode electrodes CE1, CE2, and CE3 may not be directly connected to each other, and may be electrically connected to each other through the first bank layer 161 of the bank structure 160.

The thin film encapsulation layer 170 may be disposed on the display element layer 150. The thin film encapsulation layer 170 may include at least one inorganic film to prevent or substantially impede oxygen or moisture from permeating into the display element layer 150. The thin film encapsulation layer 170 may include at least one organic film to protect the display element layer 150 from foreign substances such as dust. The thin film encapsulation layer 170 according to some embodiments may include a first encapsulation layer 171, a second encapsulation layer 172, a third encapsulation layer 173, and a fourth encapsulation layer 175 that are sequentially stacked.

The first encapsulation layer 171 according to some embodiments may be positioned on the light emitting element ED in a portion overlapping with the emission area EA. The first encapsulation layer 171 according to some embodiments may not overlap with the non-emission area NLA. The first encapsulation layer 171 may be formed through a chemical vapor deposition (CVD) process, and may thus be formed at a uniform thickness along a profile of an underlying structure.

The first encapsulation layer 171 may include an inorganic material such as aluminum oxide, titanium oxide, tantalum oxide, hafnium oxide, zinc oxide, silicon oxide, silicon nitride, and/or silicon oxynitride.

The first encapsulation layer 171 according to some embodiments may include a first inorganic layer 171-1, a second inorganic layer 171-2, and a third inorganic layer 171-3 positioned to respectively overlap with the first to third emission areas EA1, EA2, and EA3 (e.g., in a plan view). The first inorganic layer 171-1, the second inorganic layer 171-2, and the third inorganic layer 171-3 may be spaced apart from each other in the first direction (e.g., X-axis direction) with the bank structure 160 interposed therebetween.

It has been illustrated in FIG. 5 that the first to third inorganic layers 171-1, 171-2, and 171-3 are formed at the same layer, but the first to third inorganic layers 171-1, 171-2, and 171-3 may be formed in different processes, respectively. As an example, the first inorganic layer 171-1 may be formed after the first cathode electrode CE1 is formed, the second inorganic layer 171-2 may be formed after the second cathode electrode CE2 is formed, and the third inorganic layer 171-3 may be formed after the third cathode electrode CE3 is formed. The fabricating process will be described later.

The second encapsulation layer 172 according to some embodiments may be entirely positioned on the first encapsulation layer 171 and the bank structure 160. The second encapsulation layer 172 may be positioned on the first encapsulation layer 171 in a portion overlapping with the emission area EA, and may be positioned on the bank structure 160 in a portion overlapping with the non-emission area NLA. The second encapsulation layer 172 may be formed through a CVD process, and may thus be formed at a uniform thickness along a profile of an underlying structure.

The second encapsulation layer 172 may include the same material(s) as the first encapsulation layer 171. The second encapsulation layer 172 may prevent or substantially impede oxygen or moisture from permeating into the first encapsulation layer 171 and the bank structure 160.

The third encapsulation layer 173 may be positioned on the second encapsulation layer 172. The third encapsulation layer 173 may planarize a step formed by the second encapsulation layer 172.

The third encapsulation layer 173 may include a polymer-based material. The polymer-based material may include an acrylic resin, an epoxy-based resin, a silicone resin, a silicone acrylic resin, polyimide, polyethylene, and/or the like.

The fourth encapsulation layer 175 may be positioned on the third encapsulation layer 173. The fourth encapsulation layer 175 may include the same material(s) as the first encapsulation layer 171 and the second encapsulation layer 172. The fourth encapsulation layer 175 may prevent or substantially reduce oxygen or moisture from permeating into the third encapsulation layer 173.

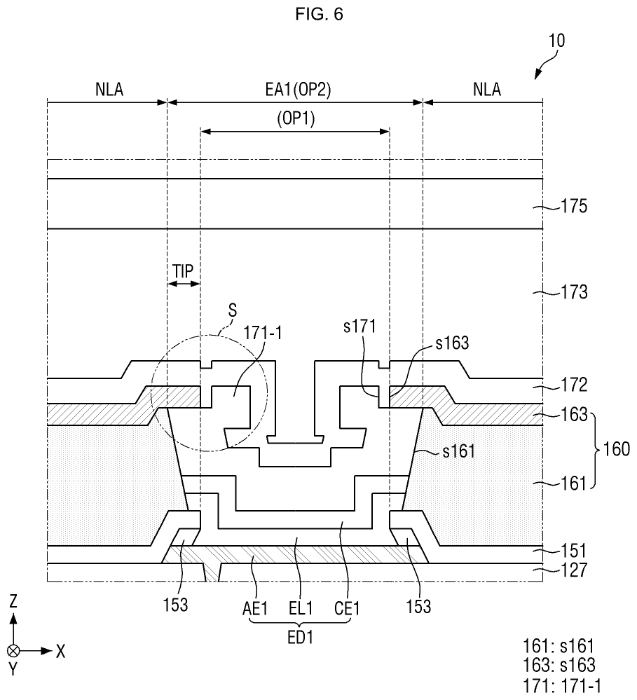

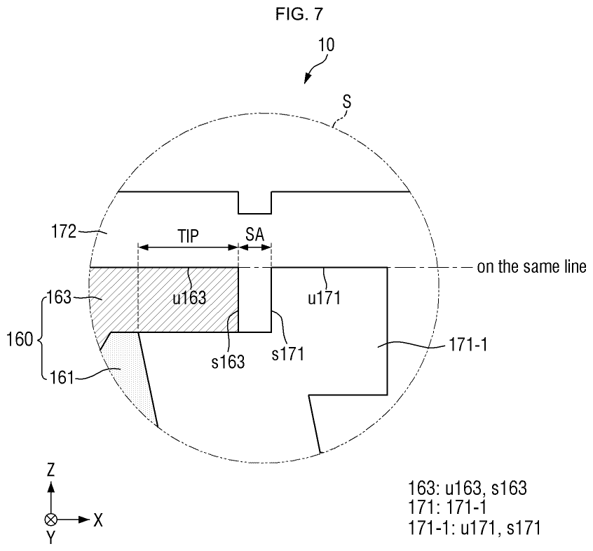

FIG. 6 is a schematic enlarged cross-sectional view of a first emission area EA1 in FIG. 5, according to some embodiments of the present disclosure. FIG. 7 is an enlarged cross-sectional view of area S in FIG. 6, according to some embodiments of the present disclosure.

Referring to FIG. 6, the pixel defining layer 151 according to some embodiments may be spaced apart from the first anode electrode AE1 in the third direction (e.g., Z-axis direction) in a portion overlapping with the second opening OP2. The residual patterns 153 may be positioned between the pixel defining layer 151 and the first anode electrode AE1 in the third direction (e.g., Z-axis direction). The residual patterns 153 may be disposed in contact with both sides of the first light emitting layer EL1 in the first direction (e.g., X-axis direction), and may overlap with the tips TIP of the bank structure 160 in the third direction (e.g., Z-axis direction).

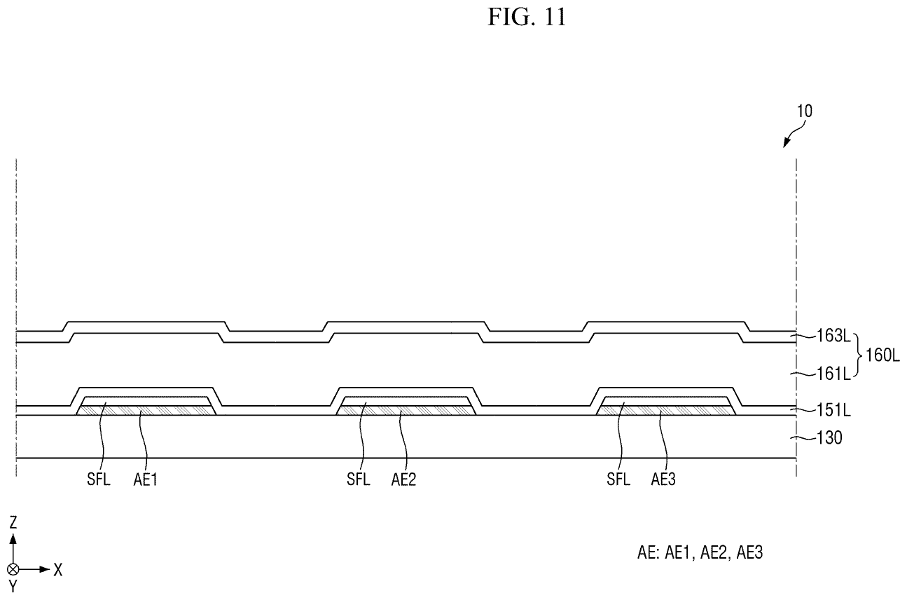

The display device 10 according to some embodiments may include a sacrificial layer SFL (see, e.g., FIG. 11) between the pixel defining layer 151 and the anode electrode AE in a fabricating process. The sacrificial layer SFL may be disposed between the pixel defining layer 151 and the first anode electrode AE1 and then partially removed by a subsequent wet etching process. In this case, portions of the sacrificial layer SFL that are not removed may remain as the residual patterns 153 between the pixel defining layer 151 and the first anode electrode AE1.

The bank structure 160 may be positioned on the pixel defining layer 151. The bank structure 160 may include a first bank layer 161 and a second bank layer 163 including different metal materials and structures and playing different roles.

The first bank layer 161 according to some embodiments may be positioned on the pixel defining layer 151 so as to be in contact with the pixel defining layer 151. The first bank layer 161 may include metal having high electrical conductivity, such as aluminum (Al).

In some embodiments, the first bank layer 161 may include a side surface s161 facing the first opening OP1. The side surface s161 of the first bank layer 161 may be an inclined surface. In other words, the side surface s161 of the first bank layer 161 may be inclined between the first direction (X-axis direction) and the third direction (e.g., Z-axis direction). That is, the side surface s161 of the first bank layer 161 may include a structure in which it is depressed more than the pixel defining layer 151 in the first direction (e.g., X-axis direction).

The first light emitting layer EL1, the first cathode electrode CE1, and the first inorganic layer 171-1 may be in contact with the side surface s161 of the first bank layer 161. In other words, the side surface s161 of the first bank layer 161 may be completely covered by the first light emitting layer EL1, the first cathode electrode CE1, and the first inorganic layer 171-1. In the fabricating process of the display device 10 according to some embodiments, a step coverage of a process of forming the first cathode electrode CE1 may be higher than a step coverage of a process of forming the first light emitting layer EL1. For this reason, the first cathode electrode CE1 may completely cover the first light emitting layer EL1.

The second bank layer 163 according to some embodiments may be positioned on the first bank layer 161. The second bank layer 163 may include a material having a lower etch rate than the first bank layer 161 and having higher hardness than the first encapsulation layer 171. As an example, the second bank layer 163 may include at least one of tungsten, titanium nitride, and molybdenum.

In some embodiments, the second bank layer 163 may include a side surface s163 facing the first opening OP1. The side surface s163 of the second bank layer 163 may have a shape in which it protrudes more than the side surface s161 of the first bank layer 161 toward the first opening OP1. In other words, the side surface s161 of the first bank layer 161 may have a shape in which it is depressed inward from the side surface s163 of the second bank layer 163. For this reason, the second bank layer 163 may include the tip TIP protruding toward the first opening OP1, and an undercut may be formed between a lower portion of the tip TIP of the second bank layer 163 and the side surface s161 of the first bank layer 161.

The first encapsulation layer 171 according to some embodiments may be positioned on the first cathode electrode CE1 in a portion overlapping with the first emission area EA1. For example, the first inorganic layer 171-1 included in the first encapsulation layer 171 may be positioned in contact with the first cathode electrode CE1 at a portion overlapping with the first opening OP1, and may be positioned in contact with the first bank layer 161 and the second bank layer 163 in a portion overlapping with the opening OP2. The first encapsulation layer 171 according to some embodiments may not overlap with the non-emission area NLA. In some embodiments, a capping layer may be included between the first encapsulation layer 171 and the first cathode electrode CE1.

In some embodiments, the first encapsulation layer 171 according to some embodiments may include a side surface s171. The side surface s171 of the first encapsulation layer 171 may be spaced apart from the side surface s163 of the second bank layer 163 in the first direction (e.g., X-axis direction) with the second encapsulation layer 172 interposed therebetween, and may face the side surface s163 of the second bank layer 163.

Referring to FIG. 7, a spaced space (e.g., gap or separation) SA may be formed between the side surface s171 of the first encapsulation layer 171 and the side surface s163 of the second bank layer 163, and may be filled with the second encapsulation layer 172.

The display device 10 according to some embodiments may temporarily include a material forming the first light emitting layer EL1 and a material forming the first cathode electrode CE1, on the second bank layer 163 in the fabricating process. The material forming the first light emitting layer EL1 and the material forming the first cathode electrode CE1, which are formed on the second bank layer 163, may be removed by a subsequent etching process, and for this reason, the spaced space SA may be formed between the side surface s171 of the first encapsulation layer 171 and the side surface s163 of the second bank layer 163. That is, the spaced space SA positioned between the side surface s171 of the first encapsulation layer 171 and the side surface s163 of the second bank layer 163 may be a portion where the material forming the first light emitting layer EL1 and the material forming the first cathode electrode CE1 were temporarily positioned in the fabricating process of the display device 10.

In some embodiments, the first encapsulation layer 171 may further include an upper surface u171. The upper surface u171 of the first encapsulation layer 171 may be one surface connected to the side surface s171 of the first encapsulation layer 171, and may be positioned on one side in the third direction (e.g., Z-axis direction). In addition, the second bank layer 163 may further include an upper surface u163. The upper surface u163 of the second bank layer 163 may be one surface connected to the side surface s163 of the second bank layer 163, and may be positioned on one side in the third direction (e.g., Z-axis direction). In other words, the upper surface u163 of the second bank layer 163 may be positioned in a direction opposite to a direction in which the first bank layer 161 is positioned.

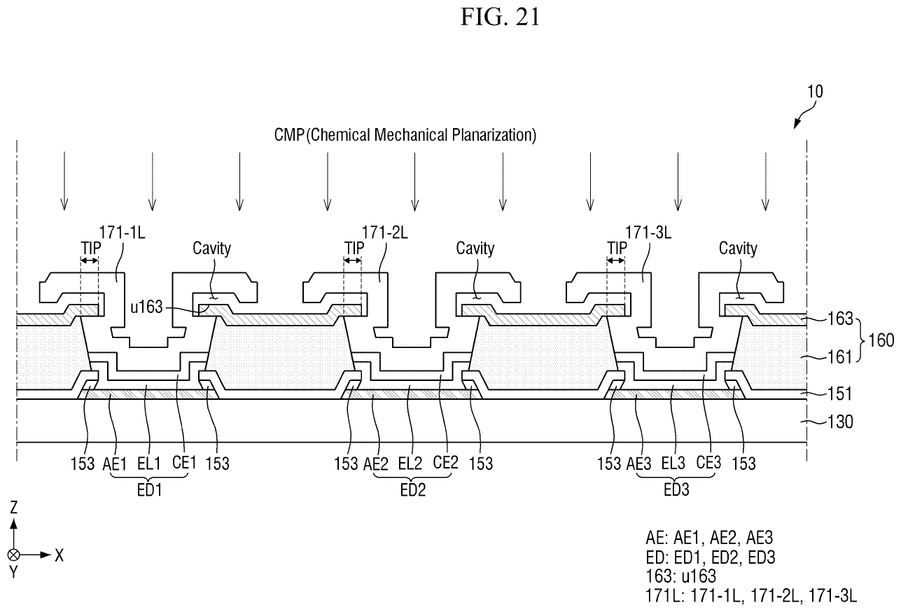

In the display device 10 according to some embodiments, a portion of the first encapsulation layer 171 may be removed by performing a chemical mechanical planarization (CMP) process CMP (see, e.g., FIG. 21) to be described later in the fabricating process. The CMP process described above may be performed until the upper surface u171 of the first encapsulation layer 171 is positioned on the same line as the upper surface u163 of the second bank layer 163. For this reason, the upper surface u171 of the first encapsulation layer 171 according to some embodiments may be positioned on the same line as the upper surface u163 of the second bank layer 163, which is positioned to overlap with the protruding tip TIP of the second bank layer 163, in the first direction (e.g., X-axis direction). In other words, the upper surface u171 of the first encapsulation layer 171 and the upper surface u163 of the second bank layer 163 may be at the same plane or substantially the same plane. However, there may be a difference within the range of about 0.04 um or less due to a CMP process error. The fabricating process will be described later.

As illustrated in FIGS. 6 and 7, the second encapsulation layer 172 according to some embodiments may completely cover the first encapsulation layer 171 and the second bank layer 163 in a portion overlapping with the first emission area EA1 and the non-emission area NLA. That is, the upper surface u163 of the second bank layer 163 may be entirely covered by the second encapsulation layer 172, and may be in entire contact with (e.g., entirely in contact with) the second encapsulation layer 172.

The third encapsulation layer 173 and the fourth encapsulation layer 175 according to some embodiments may completely cover the first encapsulation layer 171 and the second bank layer 163 in the portion overlapping with the first emission area EA1 and the non-emission area NLA (e.g. in a plan view.

For convenience of explanation, the first light emitting element ED1 and the bank structure 160 positioned to overlap with the first emission area EA1 have been illustrated and described, but the light emitting elements ED and the bank structure 160 positioned to overlap with the second emission area EA2 and the third emission area EA3 may also have the same structure and characteristics as those described above.

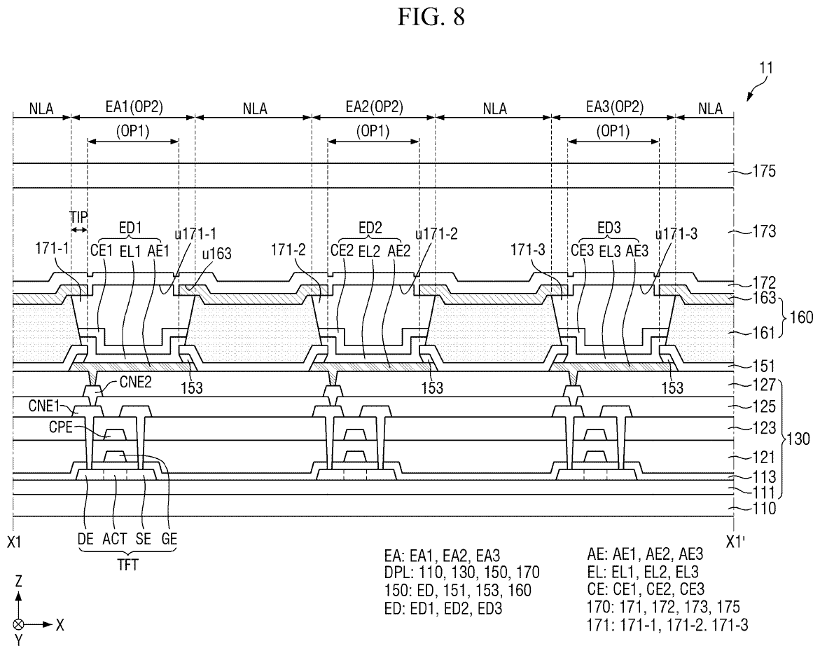

FIG. 8 is a schematic cross-sectional view of a display layer DPL taken along the line X1-X1′ of FIG. 4 according to some embodiments of the present disclosure.

Referring to FIG. 8, a first encapsulation layer 171 included in a display device 11 may have characteristics different from those of a shape of the first encapsulation layer 171 included in the display device 10. As an example, the first encapsulation layer 171 of the display device 11 may be formed to fill an underlying structure in a portion overlapping with the emission area EA. That is, the first encapsulation layer 171 of the display device 11 may planarize a step of the underlying structure.

In some embodiments, the first encapsulation layer 171 of the display device 11 may include a first inorganic layer 171-1, a second inorganic layer 171-2, and a third inorganic layer 171-3. The first inorganic layer 171-1 may include a first upper surface u171-1, the second inorganic layer 171-2 may include a second upper surface u171-2, and the third inorganic layer 171-3 may include a third upper surface u171-3.

In some embodiments, the first upper surface u171-1, the second upper surface u171-2, and the third upper surface u171-3 may be positioned on the same line in the first direction (e.g., X-axis direction). In addition, the first upper surface u171-1, the second upper surface u171-2, and the third upper surface u171-3 may also be positioned on the same line as the upper surface U163 of the second bank layer 163, which is positioned to overlap with the protruding tip TIP of the second bank layer 163, in the first direction (e.g., X-axis direction).

The display device 11 according to some embodiments may have the first upper surface u171-1, the second upper surface u171-2, and the upper surface u171-3 by performing a CMP process in a fabricating process to remove portions of the first encapsulation layer 171. An overlapping description will be omitted.

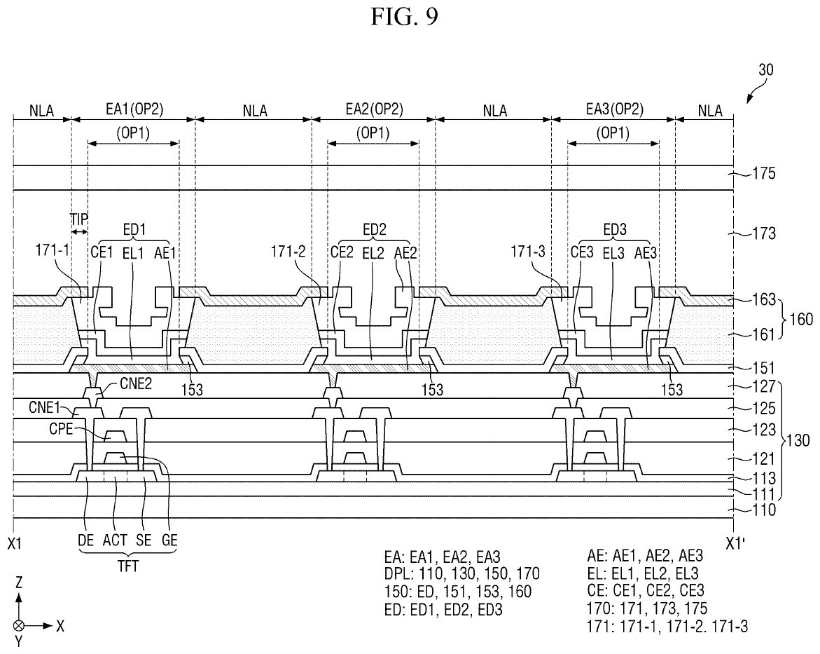

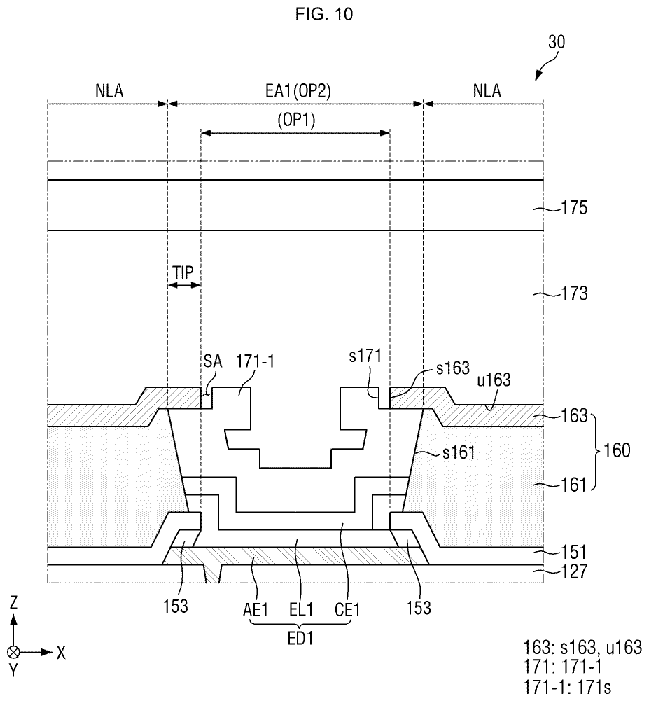

FIG. 9 is a schematic cross-sectional view of a display layer DPL taken along the line X1-X1′ of FIG. 4 according to still some embodiments of the present disclosure. FIG. 10 is a schematic enlarged cross-sectional view of a first emission area EA1 in FIG. 9, according to some embodiments of the present disclosure.

Referring to FIGS. 9 and 10, a thin film encapsulation layer 170 included in a display device 30 according to some embodiments is different from the thin film encapsulation layer 170 included in the display device 10 described above in that it includes a first encapsulation layer 171, a third encapsulation layer 173, and a fourth encapsulation layer 175. Hereinafter, an overlapping description will be omitted, and differences between the display device 30 and the display device 10 will be described later.

The second bank layer 163 according to some embodiments may include a side surface s163 protruding more than the side surface s161 of the first bank layer 161 toward the first opening OP1, and for this reason, the second bank layer 163 according to some embodiments may include a tip TIP protruding toward the first opening OP1. In addition, the upper surface u163 of the second bank layer 163 may be entirely covered by the third encapsulation layer 173, and may be in entire contact with (e.g., entirely in contact with) the third encapsulation layer 173.

The side surface s171 of the first encapsulation layer 171 and the side surface s163 of the second bank layer 163 according to some embodiments may be positioned with a spaced space SA interposed therebetween. The spaced space SA positioned between the side surface s171 of the first encapsulation layer 171 and the side surface s163 of the second bank layer 163 may be filled with the third encapsulation layer 173. In other words, the side surface s171 of the first encapsulation layer 171 and the side surface s163 of the second bank layer 163 included in the display device 30 according to some embodiments may be spaced apart from each other with the third encapsulation layer 173 interposed therebetween. Other overlapping descriptions will be omitted.

FIGS. 11 to 23 are cross-sectional views illustrating a schematic method of fabricating a display layer included in the display device of FIG. 5, according to some embodiments of the present disclosure. Hereinafter, a fabricating process of the display device 10 will be described in relation to the formation order of each layer.

Referring to FIG. 11, a plurality of anode electrodes AE, sacrificial layers SFL, a pixel defining material layer 151L, and a bank material layer 160L are formed on the thin film transistor layer 130. The bank material layer 160L may include a first bank material layer 161L and a second bank material layer 163L that are sequentially stacked. Although not illustrated in FIG. 11, the thin film transistor layer 130 may be positioned on the substrate 110, and a structure of the thin film transistor layer 130 is the same as that described above with reference to FIG. 5. A detailed description thereof will be omitted.

The plurality of anode electrodes AE may be positioned to be spaced apart from each other on the thin film transistor layer 130. As an example, the anode electrode AE may include first to third anode electrodes AE1, AE2, and AE3. The sacrificial layer SFL may be positioned on each of the first to third anode electrodes AE1, AE2, and AE3. The sacrificial layer SFL may assist in preventing an upper surface of the anode electrode AE and the pixel defining material layer 151L from being in contact with each other or substantially reducing the likelihood thereof.

The sacrificial layer SFL may include an oxide semiconductor. As an example, the sacrificial layer SFL may include at least one of indium gallium zinc oxide (IGZO), zinc tin oxide (ZTO), and indium tin oxide (IZO).

The pixel defining material layer 151L may be positioned to entirely cover the sacrificial layers SFL and the thin film transistor layer 130, the first bank material layer 161L may be positioned to entirely cover the pixel defining material layer 151L, and the second bank material layer 163L may be positioned to entirely cover the first bank material layer 161L.

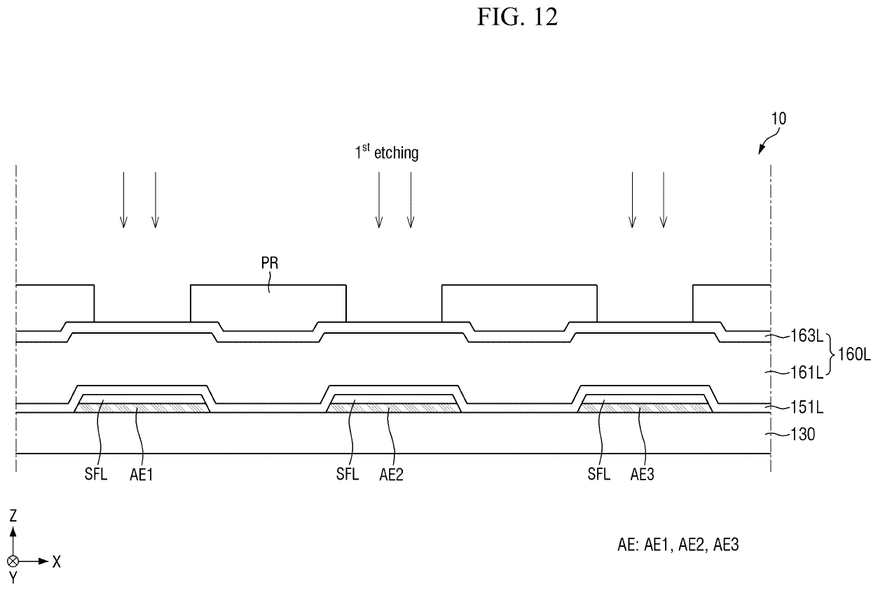

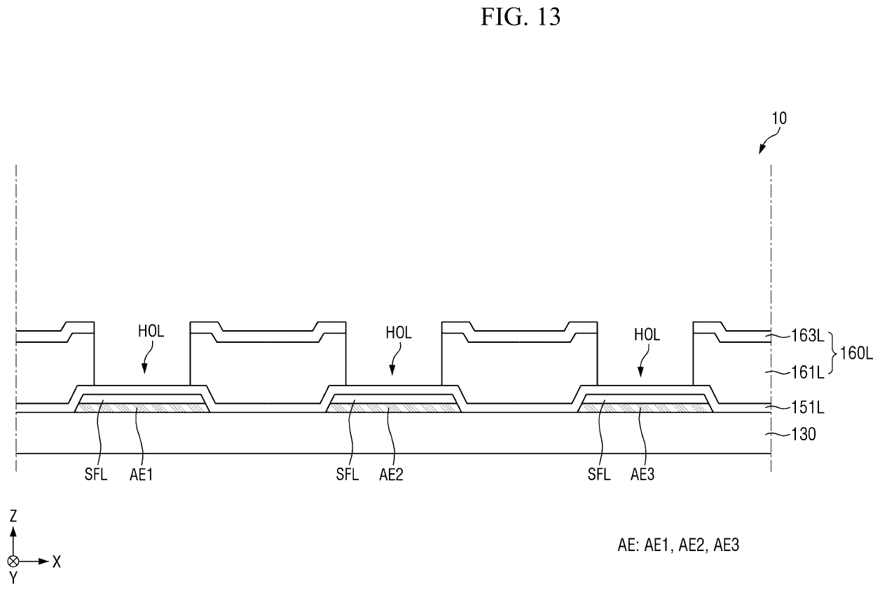

Next, referring to FIGS. 12 and 13, a plurality of photoresists PR are formed on the bank material layer 160L, and a first etching process (1^{st} etching) is performed using the photoresists PR as a mask. As an example, the first etching process (1^{st} etching) may be isotropic dry etching. The plurality of photoresists PR may be spaced apart from each other while exposing the first to third anode electrodes AE1, AE2, and AE3.

In the present process, the first bank material layer 161L and the second bank material layer 163L in portions where the photoresists PR are not formed may be isotropically removed, and for this reason, holes HOL may be formed in portions overlapping with the first to third anode electrodes AE1, AE2, and AE3 (e.g., in a plan view). In the present process, the pixel defining material layer 151L positioned to overlap with the holes HOL (e.g., in a plan view) may be exposed.

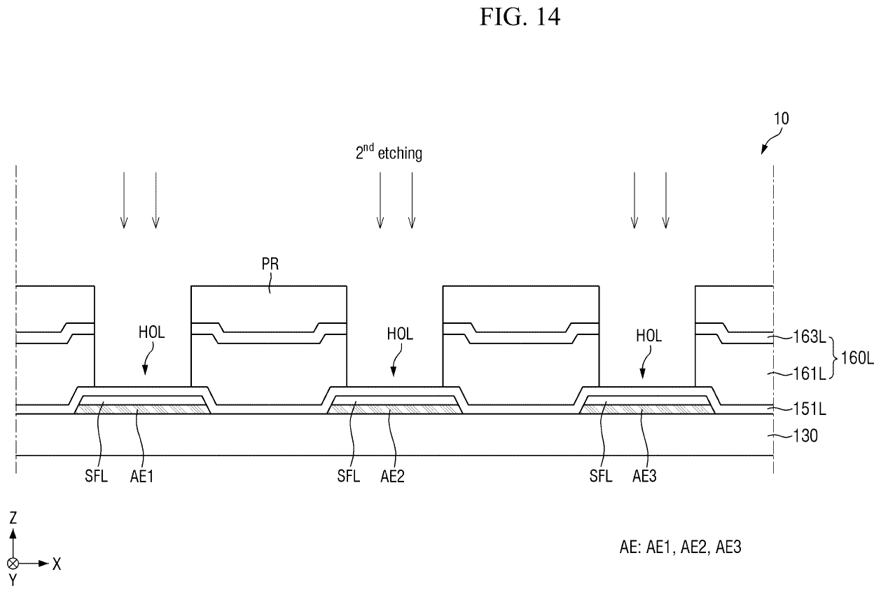

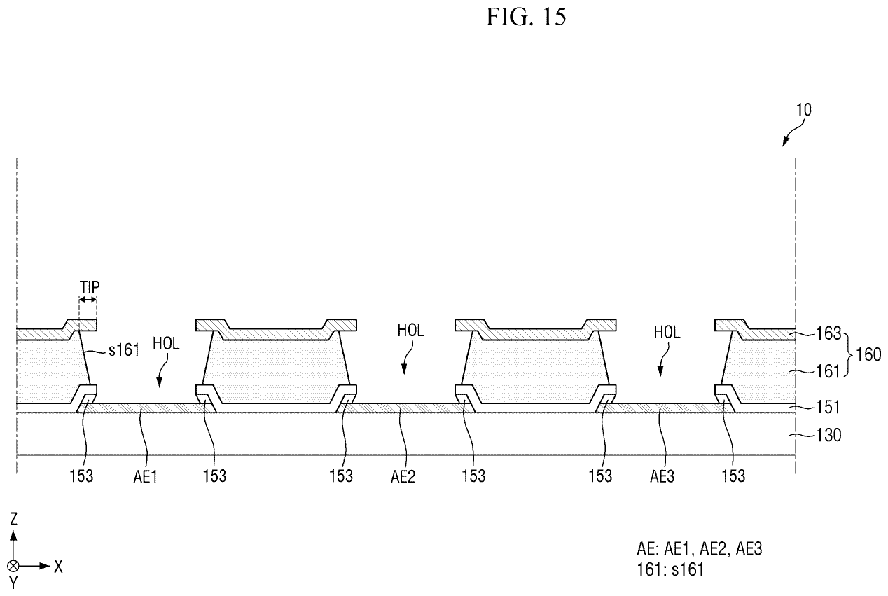

Subsequently, referring to FIGS. 14 and 15, photoresists PR are formed on the second bank material layer 163L, and a second etching process (2^{nd} etching) is then performed using the photoresists PR as a mask. As an example, in the second etching process (2^{nd} etching), wet etching processes and a dry etching process may be alternately performed.

First, the wet etching process is performed to etch portions of an inner side of the first bank material layer 161L positioned to overlap with the holes HOL. The first bank material layer 161L and the second bank material layer 163L according to some embodiments may include different materials. Accordingly, the first bank material layer 161L and the second bank material layer 163L may have different etch rates in the same etching process. As an example, the second bank material layer 163L may have a lower etch rate than the first bank material layer 161L. In other words, the first bank material layer 161L may have a higher etch rate than the second bank material layer 163L. Accordingly, the second bank material layer 163L according to some embodiments may have tips TIP protruding more than side surfaces s161 of the first bank material layer 161L to both sides toward the holes HOL, and undercuts may be formed between the side surfaces s161 of the first bank material layer 161L and the tips TIP of the second bank material layer 163L. In the present process, the first bank material layer 161L may be formed in the shape of the first bank layer 161 illustrated in FIG. 5, and the second bank material layer 163L may be formed in the shape of the second bank layer 16 illustrated in FIG. 5.

Subsequently, second, the dry etching process is performed to remove portions of the pixel defining material layer 151L overlapping with the anode electrodes AE, such that the pixel defining layer 151 illustrated in FIG. 5 is formed and the sacrificial layers SFL positioned to overlap with the first to third anode electrodes AE1, AE2, and AE3 (e.g., in a plan view) are exposed.

Third, the wet etching process is performed again to remove portions of the sacrificial layers SFL overlapping with the anode electrodes AE (e.g., in a plan view). In the present process, the sacrificial layers SFL may not be completely removed, and may remain as partial residual patterns 153 in spaces between the pixel defining layer 151 and the anode electrodes AE. In the present process, the first to third anode electrodes AE1, AE2, and AE3 may be exposed in portions overlapping with the holes HOL.

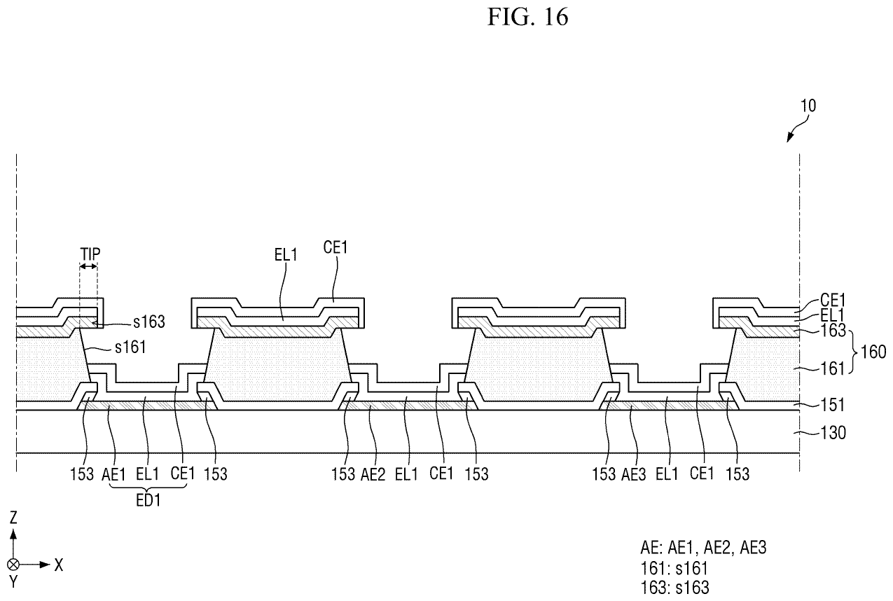

Subsequently, referring to FIG. 16, the first light emitting element ED1 is formed by depositing the first light emitting layer EL1 and the first cathode electrode CE1 on the first anode electrode AE1. In the display device 10 according to some embodiments, the second bank layer 163 includes the tips TIP, and accordingly, the first light emitting layer EL1 and the first cathode electrode CE1 may be formed on the first anode electrode AE1 through deposition and photo pattern processes without a separate fine metal mask.

For example, the first light emitting layer EL1 according to some embodiments may be formed through a thermal deposition process. The deposition process of forming the first light emitting layer EL1 according to some embodiments may be performed at an inclined angle of 45° to 50° from an upper surface of the first anode electrode AE1. For this reason, the first light emitting layer EL1 may be formed even on the pixel defining layer 151 and the side surface s161 of the first bank layer 161 that are hidden under the tip TIP of the second bank layer 163.

The first cathode electrode CE1 according to some embodiments may be formed through a thermal deposition process or a sputtering deposition process. When the first cathode electrode CE1 according to some embodiments is formed through the thermal deposition process, the deposition process of forming the first cathode electrode CE1 may be performed at an inclined angle of 30° or less from the upper surface of the first anode electrode AE1. In other words, the deposition process of forming the first cathode electrode CE1 may be performed in an inclined direction relatively closer to a horizontal direction than the deposition process of forming the first light emitting layer EL1. That is, the deposition process of forming the first cathode electrode CE1 may have a higher step coverage than the deposition process of forming the first light emitting layer EL1. For this reason, the first cathode electrode CE1 may completely cover the first light emitting layer EL1, and may be formed even on the pixel defining layer 151 and the side surface s161 of the first bank layer 161 that are hidden under the tip TIP of the second bank layer 163.

When the first cathode electrode CE1 according to some embodiments is formed through the sputtering deposition process, the deposition process of forming the first cathode electrode CE1 may have higher step coverage characteristics than the thermal deposition process. An overlapping description will be omitted.

In the present process, a material forming the first light emitting layer EL1 and a material forming the first cathode electrode CE1 may be formed on not only the first anode electrode AE1, but also the second anode electrode AE2, the third anode electrode AE3, and the second bank layer 163. In the display device 10 according to some embodiments, the second bank layer 163 has the tip TIP protruding more than the side surface s161 of the first bank layer 161, and thus, the material forming the first light emitting layer EL1 and the material forming the first cathode electrode CE1, which are formed on the second bank layer 163, may be spaced apart from the material forming the first light emitting layer EL1 and the material forming the first cathode electrode CE1, which are formed on the anode electrode AE.

As described above, the process of forming the first cathode electrode CE1 according to some embodiments may have the higher step coverage than the process of forming the first light emitting layer EL1, and thus, the material forming the first cathode electrode CE1 may also cover side surface s163 of the second bank layer 163.

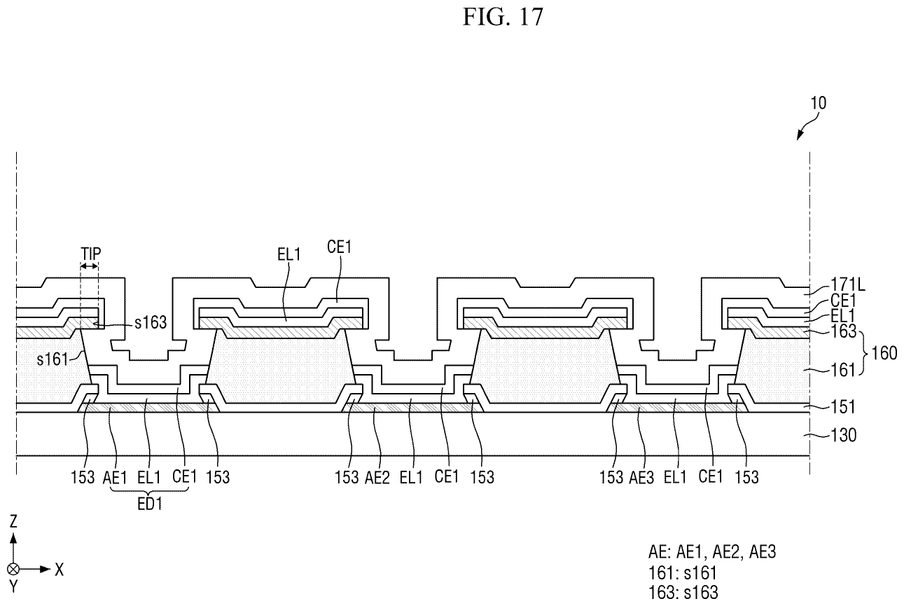

Next, referring to FIG. 17, a first encapsulation material layer 171L is formed entirely on the first cathode electrode CE1. The first encapsulation material layer 171L may be formed through a CVD process, and may be formed as a uniform film regardless of a step of an underlying structure. As an example, the first encapsulation material layer 171L may cover the side surface s161 of the first bank layer 161 and the side surface s163 of the second bank layer 163, and may also cover an undercut portion formed between the protruding tip TIP of the second bank layer 163 and the side surface s161 of the first bank layer 161.

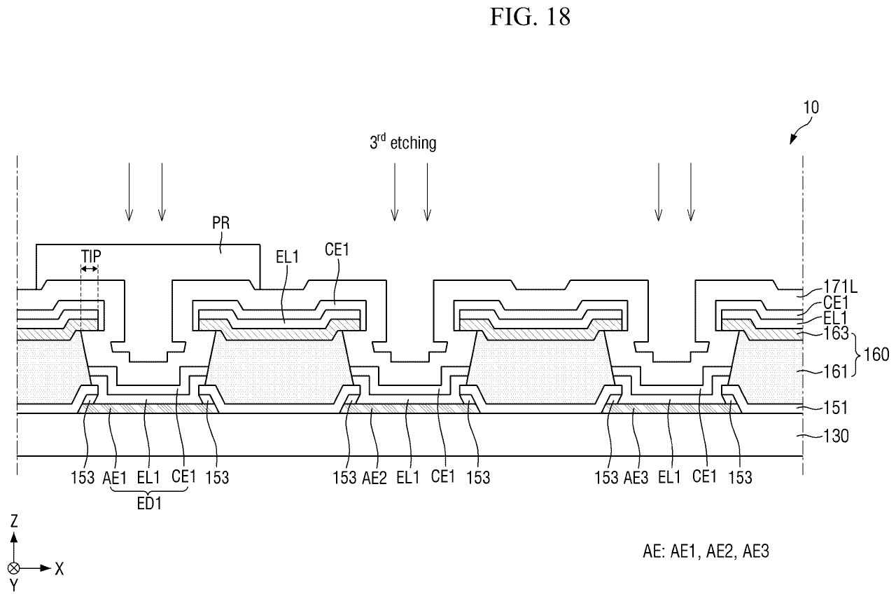

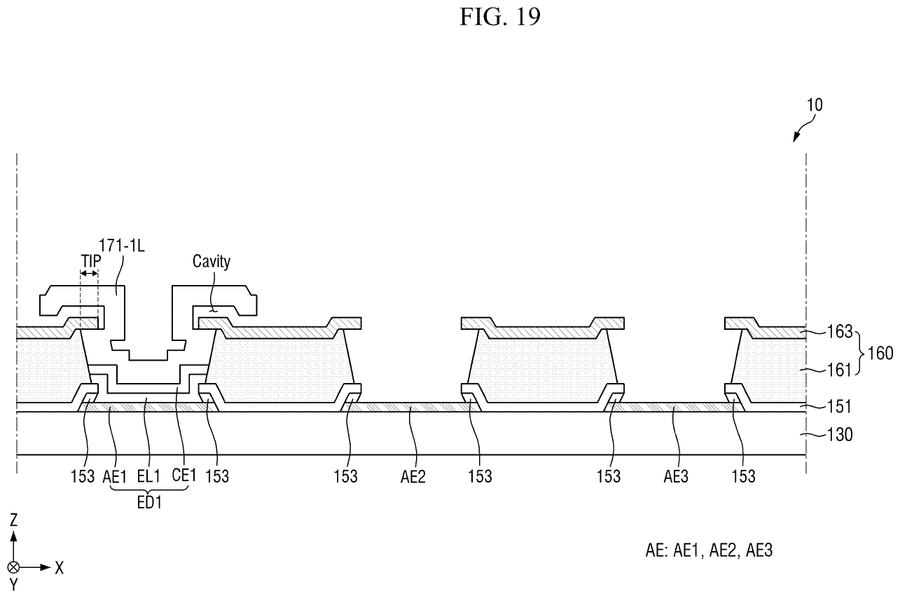

Subsequently, referring to FIGS. 18 and 19, a photoresist PR is formed on the first anode electrode AE1 and the first encapsulation material layer 171L positioned around the first anode electrode AE1, and a third etching process (3^{rd} etching) is performed. As an example, in the third etching process (3^{rd} etching), wet etching processes and dry etching processes may be alternately performed.

In the present process, the first light emitting layer EL1, the first cathode electrode CE1, and the first encapsulation material layer 171L in a portion where the photoresist PR is not formed may all be removed. For this reason, the first encapsulation material layer 171L may be formed in the shape of a first inorganic material layer 171-1L in a portion overlapping with the first light emitting element ED1. A cavity may be formed between the first inorganic material layer 171-1L and the second bank layer 163 according to some embodiments. The cavity formed between the first inorganic material layer 171-1L and the second bank layer 163 may be formed by removing the material forming the first light emitting layer EL1 and the material forming the first cathode electrode CE1, which are formed on the second bank layer 163, through the third etching process. The first inorganic material layer 171-1L and the second bank layer 163 may be spaced apart from each other in the third direction (e.g., Z-axis direction) with the cavity interposed therebetween, and may also be spaced apart from each other in the first direction (e.g., X-axis direction) with the cavity interposed therebetween.

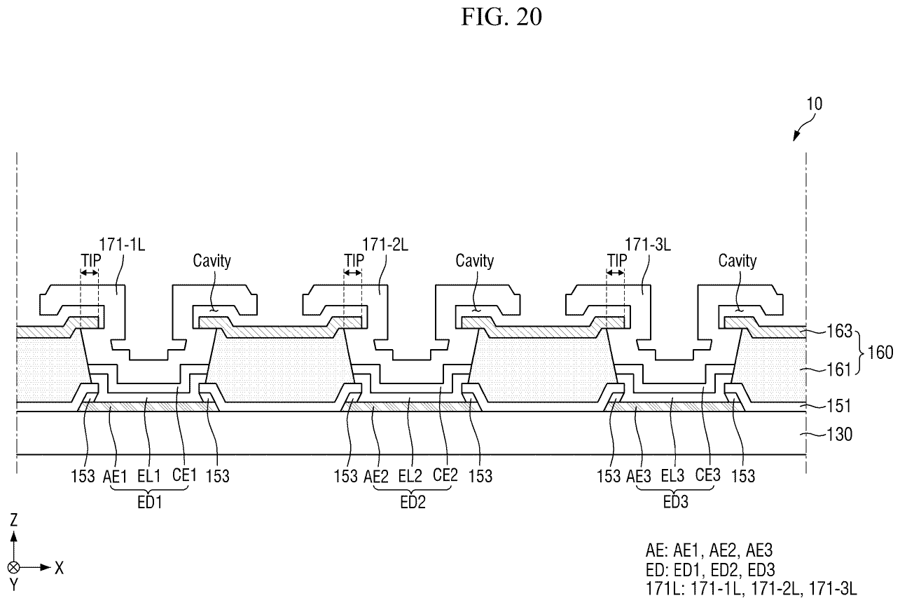

Referring to FIG. 20, the second light emitting element ED2 overlapping with the second anode electrode AE2 and the third light emitting element ED3 overlapping with the third anode electrode AE3 are formed by repeating the above-described processes. Processes of forming the second light emitting element ED2 and the third light emitting element ED3 may be the same as the processes of forming the first light emitting element ED1. An overlapping description will be omitted.

In the present process, the first encapsulation material layer 171L may be formed in the shape of a second inorganic material layer 171-2L in a portion overlapping with the second light emitting element ED2, and may be formed in the shape of a third inorganic material layer 171-3L in a portion overlapping with the third light emitting element ED3. The first inorganic material layer 171-1L, the second inorganic material layer 171-2L, and the third inorganic material layer 171-3L may be spaced apart from each other in the first direction (e.g., X-axis direction).

In the present process, a cavity may be formed between the second inorganic material layer 171-2L and the second bank layer 163, and a cavity may also be formed between the third inorganic material layer 171-3L and the second bank layer 163. For example, the second inorganic material layer 171-2L and the second bank layer 163 may be spaced apart from each other in the third direction (e.g., Z-axis direction) with the cavity interposed therebetween, and the second inorganic material layer 171-2L and the protruding tip TIP of the second bank layer 163 may be spaced apart from each other in the first direction (e.g., X-axis direction). For example, the third inorganic material layer 171-3L and the second bank layer 163 may be spaced apart from each other in the third direction (e.g., Z-axis direction) with the cavity interposed therebetween, and the third inorganic material layer 171-3L and the protruding tip TIP of the second bank layer 163 may be spaced apart from each other in the first direction (e.g., X-axis direction).

The cavity positioned between the first encapsulation material layer 171L and the second bank layer 163 may cause a device reliability defect in a subsequent reliability evaluation process. As an example, a portion where the cavity is formed may be weak in terms of device strength such as a pen drop test or a ball drop test. Accordingly, in the display device 10 according to some embodiments, in order to improve device reliability of the display device 10, a process of removing the cavity positioned between the first encapsulation material layer 171L and the second bank layer 163 according to some embodiments may be included.

Subsequently, referring to FIG. 21, a chemical mechanical planarization (CMP) process is performed to remove a portion of the first encapsulation material layer 171L. The CMP process is a technology generally used in a display process, and a detailed description thereof will be omitted. In the present process, a portion of the first encapsulation material layer 171L may be removed by first treating a portion of the first encapsulation material layer 171L with an etchant and then performing physical polishing.

The second bank layer 163 according to some embodiments may include a material having hardness similar to or higher than that of the first encapsulation material layer 171L. As an example, when a material forming the first encapsulating material layer 171L is silicon nitride, Vickers hardness of the first encapsulating material layer 171L may be about 1600 MPa, and a material whose Vickers hardness is 1600 MPa or more may be used as the material forming the second bank layer 163. For example, tungsten whose Vickers hardness is about 3430 MPa and titanium nitride whose Vickers hardness is about 2100 MPa may be used as the material forming the second bank layer 163. However, the present disclosure is not limited thereto, and the second bank layer 163 may include any material whose Vickers hardness is higher than that of the first encapsulation material layer 171L.

For this reason, in the present process, a portion of the first encapsulation material layer 171L may be removed until an upper surface of the first encapsulation material layer 171L is positioned on the same line as the upper surface u163 of the second bank layer 163 positioned in a portion overlapping with the protruding tip TIP of the second bank layer 163 by adjusting a physical polishing condition.

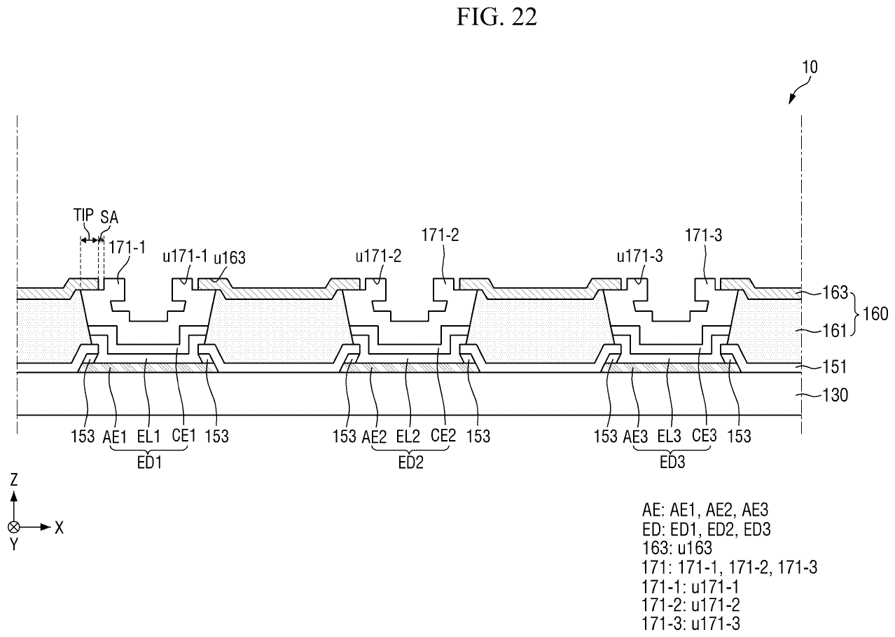

Referring to FIG. 22, through the present process, the first to third inorganic material layers 171-1L, 171-2L, and 171-3L may be formed in the shape of the first to third inorganic layers 171-1, 171-2, and 171-3 illustrated in FIG. 5. The first to third inorganic layers 171-1, 171-2, and 171-3 may be spaced apart from the tips TIP of the second bank layer 163 in the first direction (e.g., X-axis direction), and the spaced spaces SA may be formed between the tips TIP of the second bank layer 163 and the first to third inorganic layers 171-1, 171-2, and 171-3.

In the present process, the upper surface u171-1 of the first inorganic layer 171-1, the upper surface u171-2 of the second inorganic layer 171-2, and the upper surface u171-3 of the third inorganic layer 171-3 may be positioned on the same line as portions of the upper surface u163 of the second bank layer 163 positioned to overlap with the tips TIP of the second bank layer 163. In other words, the upper surface u171-1 of the first inorganic layer 171-1, the upper surface u171-2 of the second inorganic layer 171-2, and the upper surface u171-3 of the third inorganic layer 171-3 and the portions of the upper surface u163 of the second bank layer 163 positioned to overlap with the tips TIP of the second bank layer 163 may be aligned with each other in the first direction (e.g., X-axis direction). However, the meaning of the phrase “positioned on the same line as” and the meaning of the phrase “aligned with” may have a difference in the range of about 0.04 μm or less due to a CMP process error.

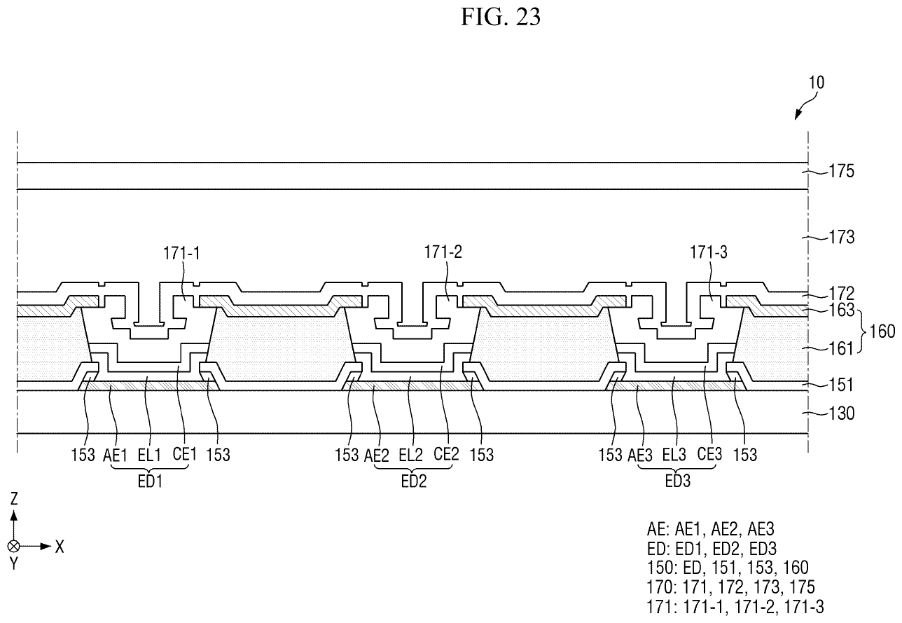

Subsequently, referring to FIG. 23, the display element layer 150 and the thin film encapsulation layer 170 illustrated in FIG. 5 may be formed by entirely forming the second encapsulation layer 172, the third encapsulation layer 173, and the fourth encapsulation layer 175 on the first encapsulation layer 171 and the second bank layer 163.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims and equivalents thereof.

What is claimed is:

1. A display device comprising:
a substrate having an emission area and a non-emission area;
an anode electrode positioned on the emission area of the substrate;
a pixel defining layer positioned on the non-emission area of the substrate and defining a first opening;
a bank structure positioned on the pixel defining layer, defining a second opening, and comprising a first bank layer and a second bank layer;
a light emitting layer positioned on the anode electrode;
a cathode electrode positioned on the light emitting layer;
a first encapsulation layer positioned on the cathode electrode and in contact with the first bank layer; and
a second encapsulation layer positioned on the first encapsulation layer,
wherein the second bank layer has a side surface facing the first opening,
wherein the first encapsulation layer has a side surface facing the second bank layer,
wherein the side surface of the second bank layer faces the side surface of the first encapsulation layer with a gap interposed therebetween, and
wherein the gap is filled with the second encapsulation layer.

2. The display device of claim 1, wherein the side surface of the second bank layer and the side surface of the first encapsulation layer are in contact with the second encapsulation layer.

3. The display device of claim 2, wherein the first encapsulation layer overlaps the emission area, and does not overlap the non-emission area.

4. The display device of claim 3, wherein the second bank layer comprises at least one of tungsten, titanium nitride, or molybdenum.

5. The display device of claim 1, wherein the second bank layer comprises a tip protruding past a side surface of the first bank layer toward the first opening.

6. The display device of claim 5, wherein the protruding tip of the second bank layer is entirely in contact with the first encapsulation layer and the second encapsulation layer.

7. The display device of claim 1, wherein in a plan view, the first opening is completely surrounded by the second opening.

8. The display device of claim 1, wherein the second bank layer further has a first surface connected to the side surface of the second bank layer and positioned in a direction opposite to a direction in which the first bank layer is positioned, and
wherein the first encapsulation layer further has a second surface positioned at the same plane as the first surface of the second bank layer and positioned to overlap with a protruding tip of the second bank layer, in a direction parallel to the substrate.

9. The display device of claim 8, wherein the first surface and the second surface are spaced apart from each other with the second encapsulation layer interposed therebetween.

10. The display device of claim 9, wherein the first surface of the second bank layer is entirely in contact with the second encapsulation layer.

11. The display device of claim 1, further comprising a third encapsulation layer positioned on the second encapsulation layer and a fourth encapsulation layer positioned on the third encapsulation layer,
wherein the second encapsulation layer comprises an inorganic insulating material.

12. The display device of claim 1, further comprising a third encapsulation layer positioned on the second encapsulation layer,
wherein the second encapsulation layer comprises an organic material.

13. The display device of claim 5, further comprising a residual pattern positioned between the anode electrode and the pixel defining layer in a direction perpendicular to the substrate,
wherein the residual pattern is in contact with the light emitting layer, and
wherein the residual pattern overlaps the protruding tip of the second bank layer.

14. The display device of claim 1, wherein a side surface of the first bank layer is in contact with the light emitting layer, the cathode electrode, and the first encapsulation layer, and
wherein the side surface of the first bank layer is entirely covered by the light emitting layer, the cathode electrode, and the first encapsulation layer.

15. The display device of claim 14, wherein the cathode electrode is electrically connected to the first bank layer.

16. A method of fabricating a display device, the method comprising:
forming a substrate having an emission area and a non-emission area, forming an anode electrode on the emission area of the substrate and forming a sacrificial layer on the anode electrode;
forming a pixel defining layer entirely covering the sacrificial layer and the substrate;
forming a bank structure comprising a first bank layer and a second bank layer that entirely covers the pixel defining layer;
forming a photoresist exposing the anode electrode and positioned on the bank structure, and performing a first etching process to remove portions of the bank structure, the pixel defining layer, and the sacrificial layer in a portion where the photoresist is not formed, thereby forming a hole overlapping with the anode electrode;
depositing a light emitting layer, a cathode electrode, and a first encapsulation layer on the anode electrode and the bank structure, forming a photoresist on the anode electrode and a portion overlapping a periphery of the anode electrode, and then performing a second etching process to remove the light emitting layer, the cathode electrode, and the first encapsulation layer positioned in a portion where the photoresist is not formed, thereby forming a light emitting element and at the same time, forming a cavity between the second bank layer and the first encapsulation layer in a direction perpendicular to the substrate; and
performing a chemical mechanical planarization (CMP) process to remove a portion of the first encapsulation layer, thereby removing the cavity and then forming a second encapsulation layer entirely covering the first encapsulation layer and the second bank layer.

17. The method of fabricating a display device of claim 16, wherein in the performing of the first etching process, the second bank layer comprises a tip protruding past a side surface of the first bank layer toward the hole.

18. The method of fabricating a display device of claim 17, wherein in the performing of the CMP process, the protruding tip of the second bank layer is spaced apart from the first encapsulation layer with a space therebetween in a direction parallel to the substrate.

19. The method of fabricating a display device of claim 18, wherein in the performing of the CMP process, the space formed between the protruding tip of the second bank layer and the first encapsulation layer is filled with the second encapsulation layer.

20. The method of fabricating a display device of claim 19, wherein the second bank layer comprises at least one of tungsten, titanium nitride, or molybdenum.
